(19) United States
(12) Patent Application Publication
(10) Pub. No.: US 2009/0242011 A1
(43) Pub. Date: Oct. 1, 2009

(54) INSTALLATION OF TELECONTROLLED PHOTOVOLTAIC MODULES

(75) Inventors: Bernard PROISY, SOLAIZE (FR); Philippe DUMAS, SAINT CHEF (FR); Valery AUROUSSEAU, L'ISLE D' ABEAU (FR)

Correspondence Address: CANTOR COLBURN, LLP, 20 Church Street, 22nd Floor, Hartford, CT, 06103, US

(73) Assignee: PHOTOWATT INTERNATIONAL, BOURGOIN JALLIEU (FR)

(21) Appl. No.: 12/372,875

(22) Filed: Feb. 18, 2009

(30) Foreign Application Priority Data
Feb. 19, 2008 (FR) 08/00872

(51) Int. Cl. H01L 31/042

(52) U.S. Cl. 136/244

(57) ABSTRACT

The invention relates to an installation of photovoltaic modules including a “control command” device, a set of photovoltaic modules, intended to transform the solar energy into electric current, having power terminals, each photovoltaic module including a breaker commanding the passage of a current across the power terminals, control means designed to control the breaker, communication means designed to allow communication between the control means of the breaker of the photovoltaic module and the “control command” device of the installation, where each photovoltaic module furthermore includes addressing means designed to identify in a unique manner a photovoltaic module and/or a group of photovoltaic modules and measurement means for measuring at least one operating parameter of the photovoltaic module.

### TECHNICAL FIELD OF THE INVENTION

The invention relates to an installation of modules of photovoltaic cells.

### BRIEF SUMMARY OF RELATED ART

It should be noted that a module of photovoltaic cells may preferably be called a photovoltaic module. A plane set of contiguous photovoltaic modules can also be called a photovoltaic panel. It should be noted moreover that a set of photovoltaic panels may preferably be called a photovoltaic solar field when it forms a unit for electricity production directly from solar radiation. Such fields are traditionally encountered on roofs, on terraces or else implanted in the middle of nowhere, for example with a chassis in the middle of a field or installed on a pylori.

A photovoltaic module makes it possible to create electrical energy from radiative energy from the sun and the phenomenon of photovoltaic conversion. A photovoltaic module is therefore an electrical generator which generates a voltage and provides a current when it is subjected to illumination.

In a known manner, the photovoltaic module, or a set of photovoltaic modules, is linked to electrical energy storage and/or distribution means. In particular, it is possible to link it to a DC storage battery, or to the AC distribution network.

When a failure occurs in such an electrical generator, a maintenance operation is required. An operator must determine initially the defective photovoltaic module by testing each of the photovoltaic modules. To perform this operation, he must access the whole set of photovoltaic modules, access to which is facilitated to a greater or lesser degree depending on their location. This access is all the more difficult when the photovoltaic modules are situated high up, in particular on a roof.

After having determined the defective module, the operator must isolate the photovoltaic module since it is an electrical generator. He must moreover isolate the electrical energy storage and/or distribution means in order to intervene on the generators that are turned off so as to avoid any risk of electrification or even electrocution.

Traditionally, any other energy source is easily isolated by means of a trip switch for example or a load isolating switch or else a breaker.

However, a photovoltaic module generates a DC current which exhibits the major drawback of being difficult to interrupt when the voltage is high. To circumvent this difficulty, it is advisable either to wait for night, or to cover the photovoltaic modules, this not being simple. It is possible to resort either to abrupt-opening isolators, or to use magnetic-blowout isolators, such equipment being very uncommon, or to use static cutout.

The invention aims to wholly or partly resolve these drawbacks by proposing an installation making it possible to carry out operations selectively on a photovoltaic module or a set of photovoltaic modules while requiring limited modification of the installation.

### BRIEF SUMMARY OF THE INVENTION

For this purpose, the invention comprises therefore of an installation of photovoltaic modules comprising:
a command control device,
a set of photovoltaic modules, intended to transform the solar energy into electric current, comprising power terminals, each photovoltaic module comprising:
   a breaker commanding the passage of a current across the power terminals,
   control means designed to control the breaker,
   communication means designed to allow communication between the control means of the breaker of the photovoltaic module and the control command device of the installation,
   addressing means designed to identify in a unique manner a photovoltaic module and/or a group of photovoltaic modules,
   measurement means for measuring at least one operating parameter of the photovoltaic module or of the group of photovoltaic modules,
storage means for storing and/or distribution means for distributing electrical energy, in particular an electrical circuit such as a DC battery or an electricity distribution network, linked to the power terminals of the photovoltaic modules,

the control command device being devised so as to collect in a selective manner operating parameters of a photovoltaic module or a group of photovoltaic modules, so as to control and/or stop selectively, a group of photovoltaic modules.

Such a device exhibits the considerable advantage of turning a specific photovoltaic module or a set of photovoltaic modules on or off without having to undergo time constraints, such as waiting for night for example.

By virtue of the provisions according to the invention, it also becomes possible to turn off the photovoltaic module, thus rendering the photovoltaic module unusable in the case of fraudulent theft of the photovoltaic module, by an unscrupulous person for example. Consequently, the advantage of being able to render the photovoltaic module inoperational makes it possible to discourage theft.

Moreover, such an installation makes it possible to use the communication means to transmit information useful for the maintenance or the management of the energy of buildings. Specifically, in respect of maintenance, it is possible, by virtue of the provisions according to the invention, to check the proper operation of each photovoltaic module or to indicate an anomaly. In particular, in respect of the management of the energy of buildings, the control command device allows the grouping of climatic information, such as temperature and humidity.

According to a characteristic of the invention, a plurality of photovoltaic modules are connected in series.

The series arrangement of the photovoltaic modules generates a high tension in output of the photovoltaic field formed by a plurality of modules.

According to a characteristic of the invention, the communication means consist of means using line carrier currents or RF waves.

These characteristics offer the possibility of carrying out a diagnosis of the state of a photovoltaic module or of a set of photovoltaic modules, while offering an installation which does not require any additional network cabling for the communication means.

Advantageously, the specific parameter is a current.

Preferably, the control means are disposed inside a laminated stack of glass, cells and polymer of the photovoltaic module.

According to a characteristic of the invention, the addressing means comprise an individual address and one or more group addresses corresponding to a group of photovoltaic modules or the set of photovoltaic modules of the field, designed to identify in a unique manner a photovoltaic module or a group of photovoltaic modules.

Advantageously, the installation comprises verification means for checking the integrity and/or the authenticity of a control order communicated between the control command post and a photovoltaic module.

Preferably, the verification means are designed to use an access code transmitted between the control command post and a photovoltaic module. This access control constitutes a sort of password.

According to a characteristic of the invention, the verification means are designed to use a verification code for checking the integrity of the messages. Preferably the verification code for checking the integrity is effected by “cyclic redundancy checksum” supplementing the elementary parity check. A cyclic redundancy “checksum” (“CRC 16” for example) exhibits the advantage of having a very high probability of error detection and even in certain cases may be used to reconstitute a damaged message.

### BRIEF DESCRIPTION OF THE DRAWINGS

The invention will be better understood with the aid of the detailed description set forth hereinbelow in conjunction with the appended drawing in which:

FIG. 1 is an overall diagram of the installation according to the invention.

FIG. 2 is a diagram of a portion of the installation associated with a photovoltaic module, using a first mode of communication.

FIG. 3 is a diagram of a portion of the installation associated with a photovoltaic module, using a second mode of communication.

FIG. 4 is a diagram representing a photovoltaic module.

FIG. 5 is a diagram of a data frame.

FIG. 6 is a flowchart of the interactions between the control command device and a module.

### DETAILED DESCRIPTION OF THE INVENTION

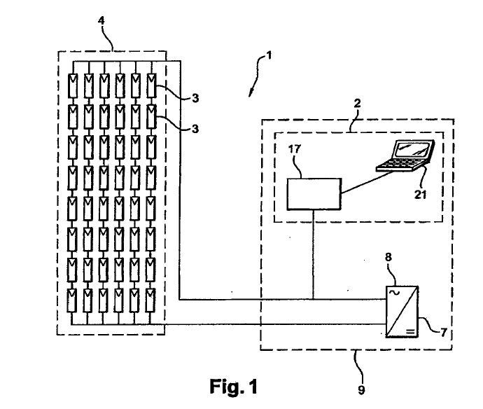

According to an embodiment as represented in FIG. 1, an installation 1 comprises a control command device 2 and a set of photovoltaic modules 3, called a photovoltaic field 4, comprising several rows each comprising a series of photovoltaic modules 3, each photovoltaic module 3 comprising a set of photovoltaic cells. It should be noted that the photovoltaic modules 3 may be equipped with bypass diodes, and in particular which Schottky diodes, connected in parallel with a view to avoiding overly significant heating of one (or more) cell(s) of a photovoltaic module in the event of shade. Such an installation 1 is intended to produce electrical energy, and in particular an electric current, from solar energy and photovoltaic conversion.

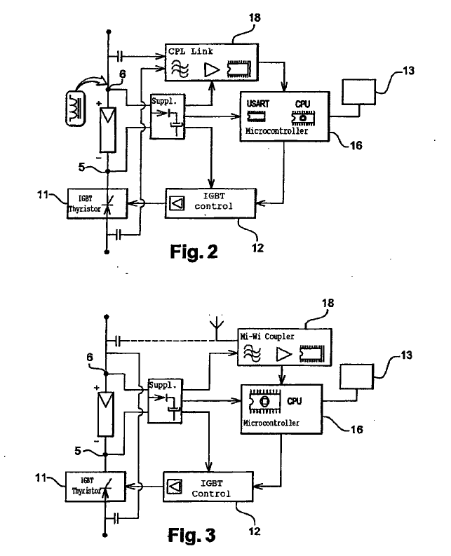

Each photovoltaic module 3 comprises two power terminals, and in particular an input power terminal 5 (−) and an output power terminal 6 (+), as represented in FIG. 2. These power terminals 5, 6 are designed to allow the connecting of the whole set of photovoltaic modules 3 to storage 7 and/or distribution 8 means, with a view to recovering the electrical energy thus produced which is available at the power terminals 5, 6 of the photovoltaic modules 3.

The storage means 7 comprise a battery. The battery is intended to store the electrical energy produced by the photovoltaic modules and to retrieve it according to demand.

The distribution means 8 comprise an inverter. An inverter is an electronic apparatus making it possible to transform the DC current of the battery and/or produced by the photovoltaic modules 3, into AC current. More precisely, the inverter converts the DC current into AC current at 230V, 50 Hz which is similar to that provided by a conventional network thus making it possible to use, for example, commercial 230V apparatus.

The storage 7 and/or distribution 8 means are grouped together in technical premises 9 in which the control command device 2 is situated.

As represented in FIGS. 2 and 3, a breaker 11 is associated with each photovoltaic module 3. The breaker 11 is positioned in series with the photovoltaic module. More precisely, it is placed in series with the chain of photovoltaic cells between the power terminals of the new telecontrollable photovoltaic module. The breaker may be set in place on the negative side or on the positive side of the photovoltaic module.

This breaker can be a static device such as an IGBT thyristor for example. Other devices may also advantageously be adopted: MOSFET transistor, GTO thyristor, etc.

The choice of the side of the cutoff is dictated only by the practical side for powering the device, on the other hand the placing of the breaker must necessarily comply with the direction of flow of the cutoff device.

It should be well understood that the choice of the breaker 11 will depend on the optimization criterion adopted.

The choice preferably adopted will either be a field-effect transistor made according to MOSFET technology or else an IGBT or GTO thyristor, which exhibit, with respect to convention transistors, great simplicity of control while retaining low conduction losses. In particular, the breaker 11, represented in FIGS. 2 and 3, is an IGBT thyristor.

The breaker 11 is intended to command the passage of a current between the power output terminals of the new photovoltaic module 3.

The photovoltaic module 3 furthermore comprises control and communication means 12-16-18, powered, preferably, by the electrical energy produced by the photovoltaic module 3 itself. These control means 12 comprise means for controlling the breaker 12a and a microcontroller 12b. They are designed to control the breaker 11. They preferably exhibit a reduced size so as to allow them to be disposed inside a laminated stack of glass and polymer of the photovoltaic module 3. This particular characteristic is intended to prevent a circumventing of the control means 12 for the use of a photovoltaic module 3 in the event of theft.

Measurement means 13 are disposed in the vicinity of each photovoltaic module 3 or situated preferably in the vicinity of the sensor associated with the quantity to measured. The measurement means 13 are designed to measure a value 13a of a specific parameter. More precisely, the measurement means 13 comprise a sensor or a set of sensors. The specific parameter measured is in particular the current which travels through the power terminals 5, 6 of a photovoltaic module 3 and/or the voltage across the power terminals 5, 6 of a photovoltaic module 3 and/or a temperature and/or other operating parameters.

Each photovoltaic module 3 comprises a first mode of operation, termed the normal mode, and a second mode of operation, termed the telecontrolled mode.

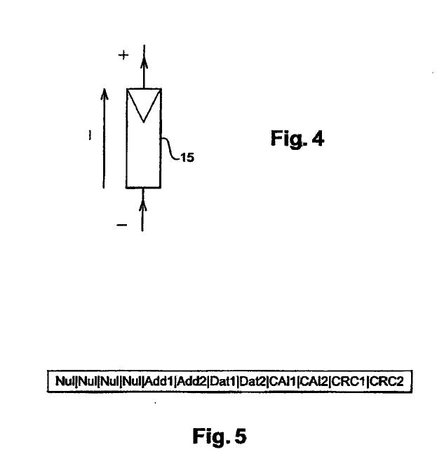

The use of the telecontrolled mode involves prior programming of the photovoltaic module 3. It entails automatic parameterization at the time that it is brought into service. The telecontrolled mode enables the photovoltaic module 3 to receive a control order 14 from the control command device 2, with the aid of the terminal 21, so as to carry out a specific application. The normal mode is the mode of operation of the photovoltaic module as it leaves the factory. It enables the photovoltaic module 3 to disregard a control order 14 received and to remain connected permanently to the whole set of photovoltaic modules 3, like a conventional photovoltaic module 15, as represented in FIG. 4.

The microcontroller 16 comprises addressing means. In particular, the addressing means comprise an individual address “Add1” corresponding to the address of the module. They furthermore comprise one or more group addresses “Add2” corresponding to groups of photovoltaic modules 3.

They are designed to identify in a unique manner a photovoltaic module 3 and/or a group of photovoltaic modules 3. Thus, the addressing means make it possible on the basis of the control command device 2 to address a control order 14 to a specific photovoltaic module 3 or to a previously determined group of photovoltaic modules 3 or to the whole set constituting the photovoltaic field 4. Moreover, the addressing means enable the control command device 2 to collect in a selective manner the value “Dat.” of the parameters measured by the measurement means 13 of a photovoltaic module 3 or of a group of photovoltaic modules 3 or of the whole set of modules 3 of a photovoltaic field 4.

The installation 1 furthermore comprises first and second communication means 17, 18 designed to allow communication between the control command device 2 of the installation 1 and the photovoltaic module 3.

According to a first embodiment as represented in FIG. 2, the communication means 17, 18 are implemented using line carrier currents.

According to a second embodiment as represented in FIG. 3, the communication means 17, 18 are implemented using RF waves. RF waves are in particular of Wi-fi, Zig-bee, Mi-Wi, Bluetooth or other types.

More precisely, the communication means 17, 18 are intended to allow communication of the control means 12 of the breaker 11 of the photovoltaic module 3 and/or of the measurement means 13 with the control command device 2. In particular, the first communication means 17 are disposed at the level of the control command device 2 and the second communication means 18 are disposed at the level of each photovoltaic module 3. The communication means 17, 18 comprise data emission means designed to send data emitted in signal form. The communication means 17, 18 furthermore comprise data reception means designed to receive data. In particular, the data emitted or received are a control command to the modules 3 or a measured parameter or a state of the breaker under signaling to the control command device 2.

To be able to communicate with one another, the control command device 2 and the photovoltaic modules 3 and in particular their communication means 17 and 18 use a specific protocol.

The protocol used is a protocol with seven levels (OSI levels of the ISO, “Open System Interoperability of the International System Organization”). These levels precisely describe the rules to be applied in order that the communication means 17, 18 of the control command device 2 and of the photovoltaic modules 3 can communicate with one another.

A sequence of the protocol is carried out using a data frame structure such as that represented for example in FIG. 5. In the example shown the minima frame is reduced to 10 bytes: an opening synchronization sequence (4 “Nul”), two address and data fields (Add-Dat), one authenticity check field (Call) and one validity check field (Crc1 & Crc2). The protocol indicated in the example described in FIG. 5 is reduced to the shortest possible with respect to the requirement and comprises addressing data, information and checks: of authenticity of emission and of quality of transmission.

In the example indicated for information in FIG. 5 the first four bytes do not contain any information and make it possible to wake up the receivers. The fifth byte Add1 contains information relating to the addressing means 16. The sixth byte Add2-Dat comprises four bits defined in respect of the address groups and four bits which code the control order 14 to be sent. It should be noted that the structure offers sixteen possibilities for the control orders that can be expressed. The seventh and eighth bytes, respectively CAl1 and CAl2 correspond to random initialization checks, namely the check code and the access code.

The ninth and tenth bytes, respectively CRC1 and CRC2, correspond to the check by cyclic redundancy code.

The control command device 2 comprises a control command post 21. The control command post 21 is equipped with a read only memory of EEPROM type. Such a read only memory is designed to record the information which must not be lost when the apparatus which contains it is no longer powered with electricity. In particular, the addresses and the control orders 14 are recorded on the read only memory.

The “control command” device 2 makes it possible, when the photovoltaic module 3 operates in telecontrolled mode, to emit a control order 14 by radio frequency (Mi-Wi for example) or line carrier current (CPL) so as to control the control means 12. The “control command” post 21 is an interface between a user and the photovoltaic module 3. When the photovoltaic module 3 is in telecontrolled mode, the “control command” post 21 makes it possible moreover to compare a value 13a measured by the measurement means 13 with respect to a value predetermined or programmed by a user. According to its programming, the “control command” post 21 emits a specific control order 14 as a function of the value 13a measured.

The installation 1 furthermore comprises verification means for checking the integrity of a control order 14 sent to a photovoltaic module 3. These verification means are recorded in a read only memory. They are intended to secure the means of communication 17, 18 between the “control command” device 2 and the photovoltaic module 3. Specifically, they make it possible to verify the right of access to the control of a photovoltaic module 3.

More precisely, the verification means use an access code 22. The access code 22 is a random code generated by means of an access code generator 22 arranged in the “control command” device 2. The random code is, in particular a number which is stored in the “control command” post 21. The access code 22 is generated at the time of initializing a site. It is created on demand and automatically by the “control command” post 21. Upon initialization, the access code 22 is communicated to the photovoltaic module 3 by the addressing means 16 by establishing a specific connection between the photovoltaic module 3 and the “control command” post 21. This access code 22 is designed to make it possible to validate the authorization to execute a control order 14.

The verification means furthermore use a verification code 23, preferably of redundancy-based cyclic type, termed CRC, or of paired random type. Such a verification code 23 is intended to verify the integrity of the control orders 14 implemented by the “control command” device 2 to the photovoltaic module 3.

The placement of the installation 1 on a site is effected in the following manner. On leaving the factory, the photovoltaic module 3 is in normal mode. Consequently, it cannot execute a control order 14 and the addressing means 16 do not operate.

Once installed on the site, each photovoltaic module 3 is initialized and programmed by means of the “control command” post 21 so as to pass to telecontrolled mode. This step makes it possible to program the photovoltaic modules 3 for a specific application.

The initialization of a photovoltaic module 3 is carried out by means of a specific connection with the “control command” post 21 of the device 2. For this purpose, a write order comprising the individual address of the photovoltaic module, the addresses of groups defined by the user beforehand, the access code 22 and the check code 23, is transmitted to the photovoltaic module 3.

The photovoltaic module 3 receives and records its individual address and as many addresses as necessary to operate with other photovoltaic modules 3 to form groups of photovoltaic modules 3.

The addressing means 16 will allow the implementation of the means of communication 17, 18 between the “control command” post 21 and a photovoltaic module 3 or a group of photovoltaic modules 3 or the whole set of photovoltaic modules 3.

Once the photovoltaic module 3 has been initialized, it can operate in telecontrolled mode.

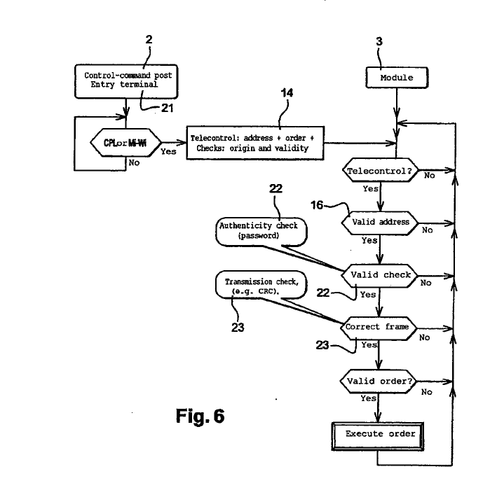

For this purpose, the “control command” device 2 sends a control order 14, as represented in FIG. 6. When the photovoltaic module 3 receives a control order 14 at its individual address, the photovoltaic module 3 verifies firstly whether this is a valid order.

A control order 14 is valid when two conditions both hold. On the one hand, the access code 22 emitted by the “control command” post 21 and received by the photovoltaic module 3, must correspond to that stored in the photovoltaic module 3 at time of initializing the installation on a site. On the other hand, the verification of the sum of the cyclic verification code 23 CRC must indicate that the message received seems to be correct.

Subsequently, the photovoltaic module 3 verifies that the control order 14 is addressed to it by virtue of the addressing means 16. It verifies that the address associated with the control order 14 corresponds to one of the addresses which it has recorded beforehand during its programming.

Thus, when the access code 22 is valid and the control order 14 is addressed to a determined photovoltaic module 3, a connection 24 is established between the “control command” post 21 and the photovoltaic module 3 and the determined photovoltaic module 3 executes the control order 14.

This control order 14 is, for example, the closing of the breaker 11. Such a control order 14 permits the passage of the current. This order is stored by the photovoltaic module 3.

When the photovoltaic module 3 no longer generates any voltage for a time determined beforehand during the programming of the photovoltaic module 3, it disconnects. This phenomenon occurs when the light disappears at nightfall. The photovoltaic module 3 is then reinitialized. A connection is again established when the photovoltaic module 3 gives a voltage again and when it receives a valid reconnection control order 14 transmitted periodically by the “control command” post 21 situated in the technical premises 9 which, preferably, are protected by a lock.

It should be noted that in the case of a change of site of installation or usage, the change of assignment of a photovoltaic module 3 is done by passing to normal mode. For this purpose, it receives a write order which must be valid in order to be executed. Thus, when the photovoltaic module 3 is switched back to normal mode, it can be programmed with a view to a new application.

It should be noted moreover that a photovoltaic module 3 which has already been initialized in telecontrolled mode in the past, may be initialized again using the access code 22 contained previously in the photovoltaic module. Finally, in the case where the user of a “control command” device 2 inadvertently loses the access code 22, it is then necessary to return the photovoltaic modules 3 to the factory to reprogram them so that they operate in normal mode. Specifically, the use of a secure procedure is necessary in this case.

Although the invention has been described in connection with particular exemplary embodiments, it is obvious that it is in no way limited thereto and that it comprises all the technical equivalents of the means described as well as their combinations if the latter come within the scope of the invention.

1. An installation of photovoltaic modules comprising
a command control device,
a set of photovoltaic modules, intended to transform the solar energy into electric current, comprising power terminals, each photovoltaic module comprising:
a breaker commanding the passage of a current across the power terminals,
control means designed to control the breaker,
communication means designed to allow communication between the control means of the breaker of the photovoltaic module and the control command device of the installation,
addressing means designed to identify in a unique manner a photovoltaic module and/or a group of photovoltaic modules,
measurement means for measuring at least one operating parameter of the photovoltaic module or of the group of photovoltaic modules,
storage means for storing and/or distribution means for distributing electrical energy, in particular an electrical circuit such as a DC battery or an electricity distribution network, linked to the power terminals of the photovoltaic modules,
the control command device being devised so as to collect in a selective manner operating parameters of a photovoltaic module or a group of photovoltaic modules, so as to control and/or stop selectively, a group of photovoltaic modules.

2. The installation as claimed in claim 1, in which a plurality of photovoltaic modules are connected in series.

3. The installation as claimed in claim 1, in which the communication means comprises means using line carrier currents or RF waves.

4. The installation as claimed in claim 1, in which the specific parameter is a current.

5. The installation as claimed in claim 1, in which the control means are disposed inside a laminated stack of glass and polymer.

6. The installation as claimed in claim 1, in which the addressing means comprise an individual address and one or more group addresses corresponding to a group of photovoltaic modules or the set of photovoltaic modules of the field, designed to identify in a unique manner a photovoltaic module or a group of photovoltaic modules.

7. The installation as claimed in claim 1, comprising verification means for checking the integrity and/or the authenticity of a control order communicated between the control command post and a photovoltaic module.

8. The installation as claimed in claim 7, in which the verification means are designed to use an access code transmitted between the control command post and a photovoltaic module.

9. The installation as claimed in claim 7, in which the verification means are designed to use a verification code.
